(19) United States
(12) Patent Application Publication
(10) Pub. No.: US 2007/0278588 A1
(43) Pub. Date: Dec. 6, 2007

(54) Semiconductor device and method for manufacturing the same

(76) Inventor: Kazuaki Nakajima, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/806,173

(22) Filed: May 30, 2007

(30) Foreign Application Priority Data
May 30, 2006 (JP) 2006-150411

(51) Int. Cl. H01L 29/94; H01L 21/8238

(52) U.S. Cl. 257/369; 438/199; 257/E27.064

(57) ABSTRACT

A semiconductor device manufacturing method has forming a gate insulation film on a silicon substrate having an nMOS transistor region and a pMOS transistor region, forming a first metal film on the gate insulation film and thereby forming a gate electrode of the nMOS transistor, removing the first metal film in the pMOS transistor region, forming a silicon film on the first metal film in the nMOS transistor region and on the gate insulation film in the pMOS transistor region, forming a second metal film having a work function higher than that of the first metal film on the silicon film and causing reaction between the second metal film and the silicon film and thereby forming a metal silicon compound film which serves as a gate electrode of the pMOS transistor.

### CROSS-REFERENCE TO RELATED APPLICATION

This application is based upon and claims the benefit of priority from the prior Japanese Patent Application No. 2006-150411, filed on May 30, 2006; the entire contents of which are incorporated herein by reference.

### BACKGROUND OF THE INVENTION

1. Field of the Invention

The present invention relates to a semiconductor device and a method for manufacturing the semiconductor device. In particular, the present invention relates to a semiconductor device having a dual metal gate electrode which uses a metal film as a gate electrode and a method for manufacturing such a semiconductor device.

2. Related Art

In recent years, micro-devices are being pursued to implement higher-performance MOSFETs (Metal Oxide Semiconductor Field Effect Transistors). However, there is a limit in miniaturization of devices. In the next-generation devices, therefore, scaling of a gate oxide will be difficult. Furthermore, as a result of miniaturization of devices, it has become impossible to disregard depletion of the gate electrode.

For the vacancy of the gate electrode, it is proposed to adopt a metal gate electrode structure. In the case of the metal gate electrode structure, however, the threshold value of a transistor depends on the impurity concentration of the channel region and the work function of the gate electrode. Therefore, it becomes necessary to use conductor materials having different work functions respectively for nMOS (n-channel MOS) and pMOS (p-channel MOS), i.e., a dual metal gate electrode structure. In this case, it is necessary that work functions of gate electrodes of the nMOS transistor and the pMOS transistor satisfy the relation in expression 1.
Pn<Pp (1)
where Pn is the work function of the gate electrode of the nMOS transistor, and Pp is the work function of the gate electrode of the pMOS transistor.

As an example of the metal material satisfying the expression 1, erbium (Er), yttrium (Y) or the like is used for the gate electrode of the nMOS transistor and a noble metal (such as platinum (Pt) or ruthenium (Ru)) is used for the gate electrode of the pMOS transistor.

In this case, as one of the semiconductor device manufacturing methods, the chemical vapor deposition (CVD) method or the fully siliciding (FUSI) method disclosed in Japanese Patent Application Laid-open publication No. 2005-123625 is known. When manufacturing a semiconductor device having a dual metal gate electrode by using these methods, however, the fact that characteristics are degraded and the fact that patterning is difficult pose problems. Therefore, it cannot be said that these methods are suitable for the method for manufacturing the semiconductor device having a dual metal gate electrode structure.

### SUMMARY OF THE INVENTION

According to a first aspect of the present invention, there is provided a semiconductor device manufacturing method, comprising: forming a gate insulation film on a silicon substrate having an nMOS transistor region and a pMOS transistor region; forming a first metal film on the gate insulation film and thereby forming a gate electrode of the nMOS transistor; removing the first metal film in the pMOS transistor region; forming a silicon film on the first metal film in the nMOS transistor region and on the gate insulation film in the pMOS transistor region; forming a second metal film having a work function larger than that of the first metal film on the silicon film: and causing reaction between the second metal film and the silicon film and thereby forming a metal silicon compound film which serves as a gate electrode of the pMOS transistor.

According to a second aspect of the present invention, there is provided a semiconductor device comprising: a silicon substrate comprising a device isolation region, a shallow diffused layer, and a deep diffused layer; a gate electrode of an nMOS transistor provided on the silicon substrate, the gate electrode comprising a laminated structure of the first metal film and the second metal film; and a gate electrode of a pMOS transistor provided on the silicon substrate, the gate electrode comprising the second metal film.

### BRIEF DESCRIPTION OF THE DRAWINGS

FIG. 1A shows a semiconductor device manufacturing method according to an embodiment of the present invention;

FIG. 1B shows a semiconductor device manufacturing method according to an embodiment of the present invention;

FIG. 1C shows a semiconductor device manufacturing method according to an embodiment of the present invention;

FIG. 1D shows a semiconductor device manufacturing method according to an embodiment of the present invention;

FIG. 1E shows a semiconductor device manufacturing method according to an embodiment of the present invention;

FIG. 1F shows a semiconductor device manufacturing method according to an embodiment of the present invention;

FIG. 1G shows a semiconductor device manufacturing method according to an embodiment of the present invention;

FIG. 1H shows a semiconductor device manufacturing method according to an embodiment of the present invention;

FIG. 1I shows a semiconductor device manufacturing method according to an embodiment of the present invention; and

FIG. 1J shows a semiconductor device manufacturing method according to an embodiment of the present invention.

### DETAILED DESCRIPTION OF THE INVENTION

Hereafter, embodiments of the present invention will be described. Contents of the following description are one mode carrying out the present invention. The present invention is not limited to this.

### First Embodiment

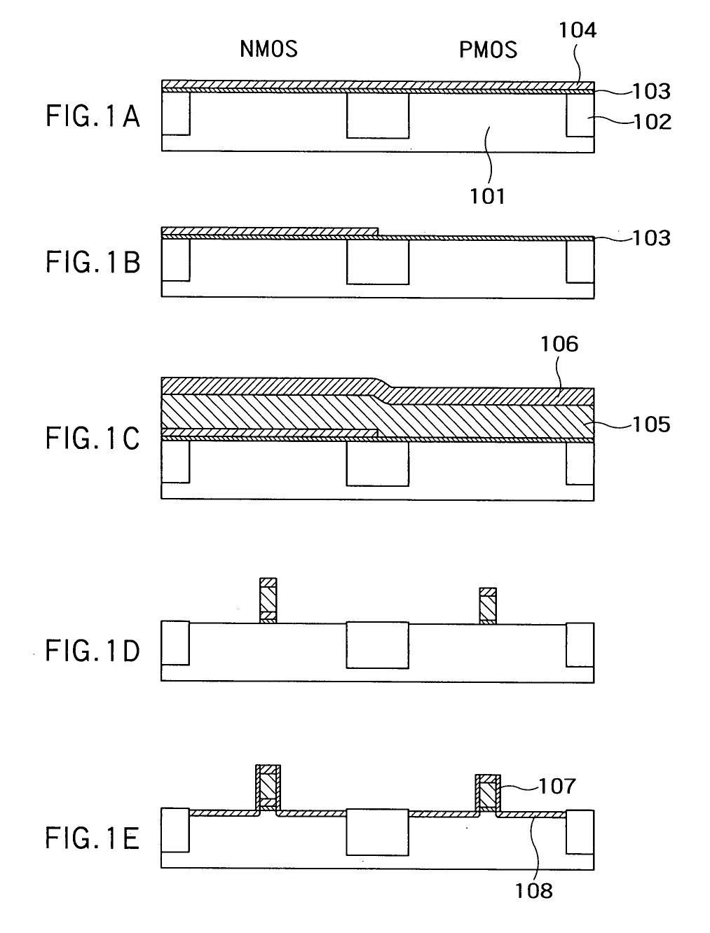

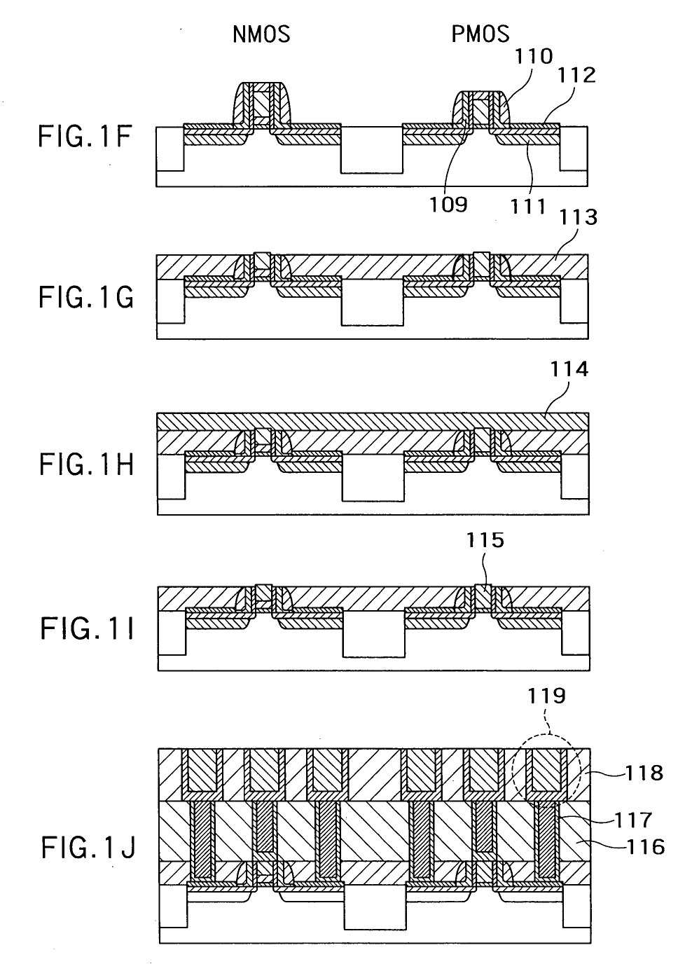

Hereafter, an embodiment of a method for manufacturing semiconductor device having a dual metal gate electrode structure according to the present invention will be described with reference to FIGS. 1A to 1J.

First, as shown in FIG. 1A, a gate insulation film 103 (film thickness=2 nm) containing hafnium (Hf) is formed on a single crystal silicon substrate 101 including device isolation regions 102. Subsequently, a barrier metal (TiSiN) film 104 (film thickness=10 nm) is formed on the gate insulation film 103. An example of a method for forming the gate insulation film 103 and the TiSiN film 104 is the CVD method.

After the process shown in FIG. 1A, the TiSiN film 104 in a pMOS region is removed as shown in FIG. 1B. An example of a method for removing the TiSiN film is a method using an aqueous solution containing hydrogen peroxide water.

After the process shown in FIG. 1B, for example, a polycrystalline silicon film 105 is deposited and then a silicon nitride film 106 (film thickness=100 nm) is deposited thereon as shown in FIG. 1C. Before forming the silicon nitride film, arsenic (As⁺) ions may be ion-implanted in the nMOS region in the polycrystalline silicon film, and boron (B⁺) ions may be ion-implanted in the pMOS region. A lower resistance can be implemented by execution of the ion implantation. When executing the ion implantation, the condition for the range in which the resistance can be lowered may be set arbitrarily as far as the polycrystalline silicon film is not penetrated.

Executing the processes shown in FIGS. 1A to 1C generates a structure in which the gate insulation film 103 in the nMOS region is in contact with the TiSiN film 104 and the gate insulation film 103 in the pMOS region is in contact with the silicon film 105.

After the process shown in FIG. 1C, the silicon nitride film 106, the polycrystalline silicon film 105 and the gate insulation film 103 are subjected to anisotropic etching, for example, to form 30-nm gate width pattern as a gate electrode pattern as shown in FIG. 1D. At this time, in the nMOS region, the TiSiN film 104 is also subjected to anisotropic etching.

After the process shown in FIG. 1D, a silicon nitride film 107 which surrounds a side wall part of the electrode pattern is formed by depositing a silicon nitride film (film thickness=5 nm) and then etching back by using the reactive ion etching (RIE) method, as shown in FIG. 1E. Subsequently, a shallow diffused layer 108 (junction depth=15 nm, peak concentration >1E21/cm³) is formed. An example of a method for forming the shallow diffused layer 108 is implanting arsenic (As⁺) ions in the nMOS region and boron (B⁺) ions in the PMOS region and conducting heating processing at 800 degree centigrade for five seconds.

After the process shown in FIG. 1E, a silicon nitride film 109 (film thickness=15 nm) and a silicon oxide film 110 (film thickness=15 nm) which surround a side wall portions of the electrode pattern are formed by depositing a nitride film (film thickness=15 nm) and a silicon oxide film (film thickness=15 nm) and then conducting etch-back by using the RIE method. Subsequently, a deep diffusion layer 111 (junction depth=45 nm, peak concentration>1E21/cm³) is formed. An example of a method for forming the deep diffused layer 111 is implanting phosphorus (P⁺) ions in the nMOS region and boron (B⁺) ions in the pMOS region and conducting heating processing at 1040 degree centigrade for five seconds. Subsequently, a silicide layer 112 is formed on the shallow diffused layer 108. The example of a method for forming the silicide layer 112 is depositing a nickel film (film thickness=10 nm) on the whole surface, conducting heating processing at 350 degree centigrade for 30 sec to cause reaction between the nickel film and the silicon substrate 101, removing the nickel film which is not yet reacted by using a mixed liquid between sulfuric acid and hydrogen peroxide water and conducting heating processing at 500 degree centigrade for 30 sec.

After the process shown in FIG. 1F, a first interlayer 113 (film thickness=250 nm) is formed and then planarized until the surface of the silicon nitride film 106 is exposed as shown in FIG. 1G. An example of a planarization method is the chemical mechanical polishing (CMP) method. Subsequently, the silicon nitride film 106 is removed so as to expose the silicon film 105 at the surface of the gate electrode by conducting etch back with the RIE method. The silicon nitride film 106 may be removed by using the CMP method.

Subsequently, for example, a platinum film 114 (film thickness=50 nm) is deposited on the whole surface of the gate electrode as shown in FIG. 1H.

After the process shown in FIG. 1H, the silicon film 105 is silicified to form a platinum silicide layer 115. An example of a silicifying method is conducting heating processing at 450 degree centigrade for 60 sec and causing reaction between the silicon film 105 and the platinum film 114. Since in the nMOS region the TiSiN film 104 which suppresses diffusion of platinum exists under the silicon film 105, platinum is prevented from being diffused below the TiSiN film 104.

Executing the processes shown in FIGS. 1A to 1I generates a structure in which the gate insulation film 103 in the nMOS region is in contact with the TiSiN film 104 and the gate insulation film 103 in the pMOS region is in contact with the platinum silicide layer 115.

After the process shown in FIG. 1I, a contact 117 is formed as shown in FIG. 1J. An example of a method for forming the contact 117 is depositing a second interlayer film 116 (film thickness=50 nm), forming a desired contact pattern thereon, burying a titanium film (film thickness=15 nm), a titanium nitride film (film thickness=20 nm) or a tungsten film (film thickness=250 nm) within the contact pattern, and conducting planarization by using the CMP method. Subsequently, copper wiring 119 for electrical connection of the contact 117 is formed. An example of a method for forming the contact 117 is depositing a third interlayer film 118 (film thickness=150 nm), forming a desired groove pattern, burying a tantalum nitride film (film thickness=10 nm) or a copper film (film thickness=150 nm), and conducting planarization by using the CMP method.

By executing the processes shown in FIGS. 1A to 1J, a semiconductor device having the dual metal gate electrode which satisfies the relation of the expression (1) can be manufactured easily.

As for work functions of the semiconductor device having the dual metal gate electrode, they may be Pn≦approximately 4.3 [eV] and Pp≧approximately 4.8 [eV].

In the first embodiment, the gate electrode material of the nMOS transistor is formed by using the CVD method, and then the pMOS electrode material is formed by using the FUSI method. In this case, the noble metal serving as the material of the gate electrode of the pMOS transistor has characteristics that patterning using the CVD method is difficult and the work function varies depending upon the heat. The metal serving as the material of the gate electrode of the nMOS transistor has a characteristic of easily reducing the gate insulation film. According to the above-described method, problems caused by these characteristics can be avoided and eventually a semiconductor device having a dual metal gate electrode can be manufactured easily. The method for generating the metal film which satisfies the relation of the expression (1) is not limited to the CVD method and the FUSI method.

### Second Embodiment

In the first embodiment, the example using TiSiN as the material of the gate electrode of the nMOS transistor has been shown. Alternatively, metal (work function=4.0 to 4.3 eV) containing a III family element (titanium (Ti), zirconium (Zr) or hafnium (Hf)) or a IV family element (vanadium (V), niobium (Nb) or tantalum (Ta)) may be used. Because these metals have work functions suitable for nMOS transistors in the dual metal gate in the same way as TiSiN.

### Third Embodiment

In the first and second embodiments, examples using platinum silicide as the material of the gate electrode of the pMOS transistor have been shown. Alternatively, nickel (Ni), rhenium (Re), rhodium (Rh), iridium (Ir) or a silicon compound (work function=4.7 to 5.2 eV) containing a combination of them may be used. Because these metals have a work function suitable for the gate electrode of the pMOS transistor in the dual metal gate and satisfy the relation of the expression (1) with respect to the metal described in the second embodiment.

### Fourth Embodiment

As another example, the gate electrode of the transistor may be made a laminated structure of a barrier metal material. Such a laminated structure is effective to the case where metal serving as the material of the gate electrode of the transistor cannot prevent metal having a high work function from being diffused. In the first to third embodiments, the examples using a Hafnium oxide film as the material of the gate insulation film have been shown. Alternatively, for example, an oxide such as zirconium (Zr), titanium (Ti), tantalum (Ta), aluminum (Al), strontium (Sr), yttrium (Y) or lanthanum (La), or an oxide of one of those elements and silicon such as ZrSixoy may be used. In addition, a laminated film of the oxide may be used.

What is claimed is:

1. A method for manufacturing a semiconductor device comprising:
forming a gate insulation film on a silicon substrate having an nMOS transistor region and a PMOS transistor region;
forming a first metal film on the gate insulation film and thereby forming a gate electrode of the nMOS transistor;
removing the first metal film in the pMOS transistor region;
forming a silicon film on the first metal film in the nMOS transistor region and on the gate insulation film in the pMOS transistor region;
forming a second metal film having a work function higher than that of the first metal film on the silicon film: and
causing reaction between the second metal film and the silicon film and thereby forming a metal silicon compound film which serves as a gate electrode of the pMOS transistor.

2. The method according to claim 1, wherein the first metal film is a metal compound film containing at least one of titanium, zirconium, hafnium, vanadium, niobium and tantalum.

3. The method according to claim 1, wherein the second metal film is a metal compound film containing at least one of platinum, nickel, palladium, rhenium, rhodium and iridium.

4. The method according to claim 1, wherein the gate insulation film is an oxide film containing at least one of zirconium, titanium, tantalum, aluminum, strontium, yttrium and lanthanum.

5. The method according to claim 1, wherein the gate insulation film forming is conducted by using the CVD method.

6. The method according to claim 1, wherein the forming of the gate electrode of the nMOS transistor comprises forming the first metal film by using the CVD method and conducting patterning using a predetermined gate electrode pattern.

7. The method according to claim 1, wherein the removing of the first metal film is conducted by using an aqueous solution which contains hydrogen peroxide water.

8. The method according to claim 1, wherein subsequently to the forming of the silicon film, a silicon nitride film is formed.

9. The method according to claim 9, wherein subsequently to the forming of the silicon nitride film, arsenic ions are implanted into the nMOS transistor region of the silicon film and boron ions are implanted into the pMOS transistor region of the silicon film.

10. The method according to claim 1, wherein the forming of the metal silicon compound film comprises causing reaction between platinum and the silicon film.

11. The method according to claim 1, wherein
the first metal film comprises metal having a work function of 4.3 eV or lower, and
the second metal film comprises metal having a work function of 4.8 eV or higher.

12. The method according to claim 1, further comprising:
forming a side wall on a side wall part of the gate electrode of the nMOS transistor and the pMOS transistor:
implanting a impurity within the nMOS transistor region and the pMOS transistor region:
forming a interlayer on the gate electrode:
removing a part of the interlayer so as to expose the silicon film: and
wherein subsequently to the polishing, the metal silicon compound film is formed.

13. The method according to claim 12, further comprising:
forming a mask on the silicon film:
forming a silicide on a source-drain region: and
wherein subsequently to the forming the silicide, the interlayer is formed.

14. A semiconductor device comprising:
a silicon substrate comprising a device isolation region, a shallow diffused layer, and a deep diffused layer;
a gate electrode of an nMOS transistor provided on the silicon substrate, the gate electrode comprising a laminated structure of the first metal film and the second metal film; and
a gate electrode of a pMOS transistor provided on the silicon substrate, the gate electrode comprising the second metal film.

15. The semiconductor device according to claim 14, wherein the first metal film comprises metal having a work function lower than that of the second metal film.

16. The semiconductor device according to claim 14, wherein the second metal film is silicide of metal having a work function higher than that of metal contained in the first metal film.

17. The semiconductor device according to claim 14, wherein the first metal film comprises metal having a work function of 4.3 eV or lower, and
the second metal film comprises metal having a work function of 4.8 eV or higher.

18. The semiconductor device according to claim 14, wherein the first metal film is a metal compound film containing at least one of titanium, zirconium, hafnium, vanadium, niobium and tantalum.

19. The semiconductor device according to claim 14, wherein the second metal film is a metal compound film containing at least one of platinum, nickel, palladium, rhenium, rhodium and iridium.
